(19) United States
(12) Patent Application Publication
(10) Pub. No.: US 2025/0308620 A1
(43) Pub. Date: Oct. 2, 2025

(54) REDUNDANCY TECHNIQUES FOR MULTI-CHANNEL MEMORY DEVICES

(71) Applicant: Micron Technology, Inc., Boise, ID (US)

(72) Inventors: Casto Salobrena Garcia, München (DE); Michael Dieter Richter, Ottobrunn (DE); Wolfgang Anton Spirkl, Germering (DE); Thomas Hein, München (DE); Peter Mayer, Neubiberg (DE)

(21) Appl. No.: 19/080,654

(22) Filed: Mar. 14, 2025

Related U.S. Application Data
(60) Provisional application No. 63/571,330, filed on Mar. 28, 2024.

(51) Int. Cl. G11C 29/00

(52) U.S. Cl. CPC G11C 29/74

(57) ABSTRACT

Methods, systems, and devices for redundancy techniques for multi-channel memory devices are described. A memory device may be configured with multiple channels (e.g., channel sets) that can be operated in different modes, such as a two-channel mode and a one-channel redundancy mode. In the two-channel mode, the memory device may be configured to access each of multiple memory arrays using a respective channel. In the one-channel redundancy mode, the memory device may be configured to access multiple memory arrays using a single channel which may otherwise be accessed using separate channels, and the memory device may store copies of data on the multiple memory arrays. For example, the memory device may store a first copy of data communicated via a channel in a first memory array and may store a second copy of the data communicated via the channel in a second memory array.

### CROSS REFERENCE

The present Application for Patent claims priority to U.S. Patent Application No. 63/571,330 by Salobrena Garcia et al., entitled “REDUNDANCY TECHNIQUES FOR MULTI-CHANNEL MEMORY DEVICES,” filed Mar. 28, 2024, which is assigned to the assignee hereof, and which is expressly incorporated by reference in its entirety herein.

### TECHNICAL FIELD

The following relates to one or more systems for memory, including redundancy techniques for multi-channel memory devices.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports redundancy techniques for multi-channel memory devices in accordance with examples as disclosed herein.

FIGS. 2 and 3 show examples of architectures that support redundancy techniques for multi-channel memory devices in accordance with examples as disclosed herein.

FIG. 4 shows a block diagram of a memory system that supports redundancy techniques for multi-channel memory devices in accordance with examples as disclosed herein.

FIG. 5 shows a block diagram of a host system that supports redundancy techniques for multi-channel memory devices in accordance with examples as disclosed herein.

FIGS. 6 and 7 show flowcharts illustrating a method or methods that support redundancy techniques for multi-channel memory devices in accordance with examples as disclosed herein.

### DETAILED DESCRIPTION

In some memory systems, a memory device may be configured with multiple channel sets. For example, each channel set may each include a command and address channel (e.g., a CA channel), a data channel (e.g., a DQ channel, an I/O channel), and one or more clock channels (e.g., a WCK channel, an RCK channel, or a combination thereof) that support coordinated signaling between the memory device and a host system. Each of the channel sets may be configured for communication of access commands and corresponding data (e.g., write data, read data) and, in some examples, may be associated with accessing a respective memory array of the memory device. For example, a first channel set may support communication of access commands being performed on a first memory array and a second channel set may support communication of access commands being performed on a second memory array. In some cases (e.g., safety-critical systems, systems involving a relatively high degree of data integrity), it may be beneficial for the memory device to support relatively low error rates for access operations performed using a particular channel set.

In accordance with examples described herein, a memory device may also be configured to access multiple memory arrays using a single channel set that may otherwise be associated with separate channel sets, and the memory device may store copies of data (e.g., redundant data) among the multiple memory arrays. For example, to write data to memory, the memory device may be configured to write a first copy of the data to a first memory array that is accessed via a first channel set and a second copy of data to a second memory array that is also accessed via the first channel set. To read data from memory, the memory device may be configured to read the first copy of the data from the first memory array, the second copy of the data from the second memory array, or both, which may support relatively low error rates and a relatively high data integrity and reliability of the memory device.

In addition to applicability in memory systems as described herein, redundancy techniques for multi-channel memory devices may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing error rates, which may increase a reliability of memory storage, increase data integrity, or otherwise improve user experience, among other benefits.

Features of the disclosure are illustrated and described in the context of systems and architectures. Features of the disclosure are further illustrated and described in the context of block diagrams and flowcharts.

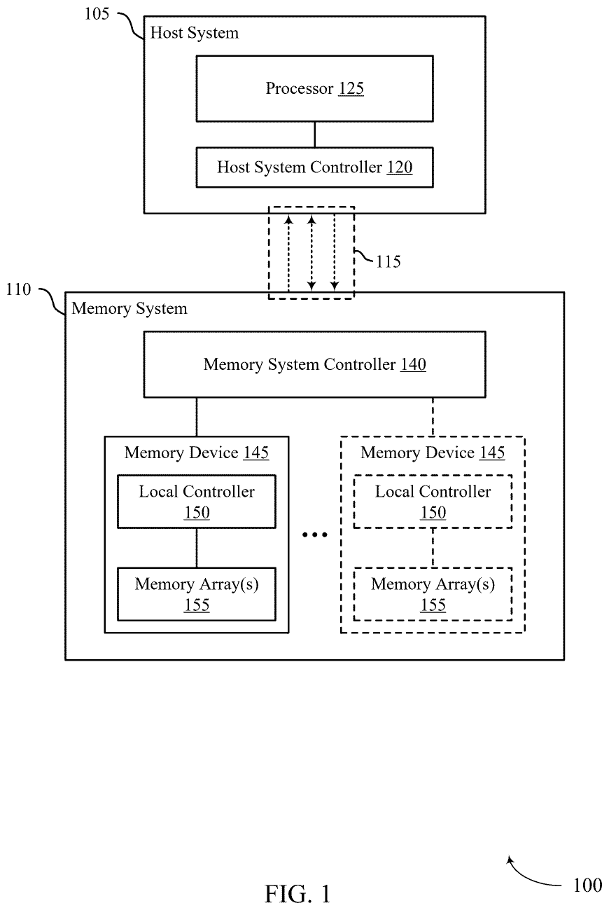

FIG. 1 illustrates an example of a system 100 that supports redundancy techniques for multi-channel memory devices in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system (e.g., a respective channel interface).

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

In some implementations, channels 115 may be configured in accordance with one or more channel sets, each of the channel sets including one or more channels 115. One or more memory arrays 155, or portions of one or more memory arrays 155, may be associated with respective channel sets such that signaling (e.g., information, commands, data, clock signaling) associated with accessing the one or more memory arrays 155 may be communicated between the host system 105 and the memory system 110 via the corresponding channel set. In some examples, a channel set may include one or more command/address channels, one or more clock signal channels, and one or more data channels.

In some examples, a memory device 145 may be configured with multiple channel sets (e.g., sets of channels 115). Each channel set may include a command and address channel (e.g., a CA channel), a data channel (e.g., a DQ channel), and one or more clock channels (e.g., a WCK channel, an RCK channel, or a combination thereof) that support coordinated signaling between the memory device 145 and a host system 105. Each of the channel sets may be configured for communication of access commands and corresponding data (e.g., write data, read data), and may be associated with accessing a respective memory array 155. For example, a first channel set may support communication of access commands being performed on a first memory array 155, or portion thereof, and a second channel set may support communication of access commands being performed on a second memory array 155 or a different portion of the first memory array 155, among other implementations. In some cases (e.g., safety-critical systems, systems involving a relatively high degree of data integrity), it may be beneficial for the memory device 145 to support relatively low error rates for access operations being performed using a particular channel set.

In accordance with examples described herein, a memory device 145 may also be configured to access multiple memory arrays 155 using a single channel set that may otherwise be associated with separate channel sets, and the memory device 145 may store copies of data (e.g., redundant data) among the multiple memory arrays 155. For example, to write data to memory, the memory device 145 may be configured to write a first copy of the data to a first memory array 155 that is accessed via a first channel set and a second copy of data to a second memory array 155 that is also accessed via the first channel set. To read data from memory, the memory device 145 may be configured to read the first copy of the data from the first memory array 155, the second copy of the data from the second memory array 155, or both, which may support relatively low error rates and a relatively high data integrity and reliability of the memory device.

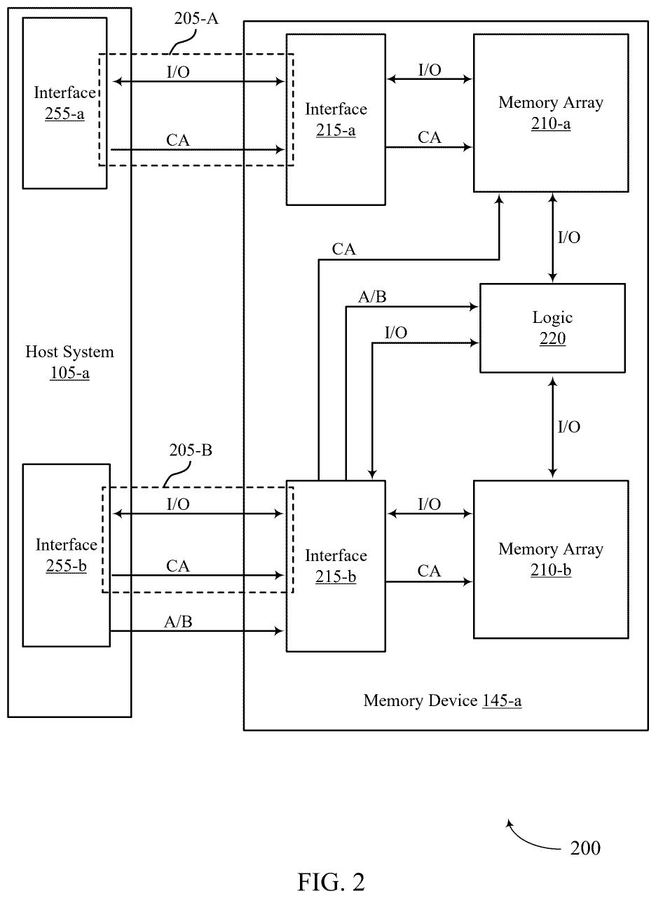

FIG. 2 shows an example of an architecture 200 that supports redundancy

techniques for multi-channel memory devices in accordance with examples as disclosed herein. The architecture 200 may implement or may be implemented by aspects of a system 100. For example, the architecture 200 may include aspects of a memory device 145-a and a host system 105-a, which may be examples of corresponding devices described herein. The memory device 145-a may include a memory array 210-a and a memory array 210-b, which may each be an example of a memory array 155, or may be portions of a same memory array 155. The architecture 200 also includes channels 205 between the host system 105-a and the memory device 145-a (e.g., between a respective interface 255 and a respective interface 215), which may each be an example of a channel set of one or more channels 115. Although the architecture 200 illustrates two channels 205, aspects of the architecture 200 may be implemented with any quantity of two or more channels 205 (e.g., in accordance with integer multiples of channel pairs, with four channels 205).

In some examples, the channel 205-a (e.g., a first channel interface) and the channel 205-b (e.g., a second channel interface) may support communication between the host system 105-a and the memory device 145-a. Each of the channels 205 may include at least a CA bus and an I/O bus (e.g., a data bus, a DQ bus). In some examples, each channel 205 may also include a clock bus (not shown) associated with one or more clock channels (e.g., a WCK channel, an RCK channel, or both). The channels 205 may be coupled with the memory device 145-a directly (e.g., without inclusion of or intervention of a memory system controller 140), or the channels 205 may be coupled with the memory device 145-a via a memory system controller 140 (not shown). Additionally, or alternatively, the channel 205-a and the channel 205-b may be coupled between a memory system controller 140 and the memory device 145-a. In some examples, the channel 205-a may be coupled with an interface 215-a and the channel 205-b may be coupled with the interface 215-b (e.g., interface circuitry). In some examples, interfaces 215 may be portions of a local controller 150 of the memory device 145-a.

In some examples, the channel 205-a may be coupled with terminals (e.g., pins, contacts, nodes) of an interface 215-a at the memory device 145-a and terminals of an interface 255-a at the host system 105-a (e.g., respective first channel interfaces), and the channel 205-b may be coupled with terminals of an interface 215-b at the memory device 145-a and terminals of an interface 255-b of the host system 105-a. The interfaces 215 and interfaces 255 may each include respective interface circuitry that is operable to support communications over at least a corresponding channel 205, such as transmitter circuitry (e.g., drivers) and receiver circuitry (e.g., latches), which may operate in accordance with clock signaling that is communicated using a same channel 205 or a different channel 205 (e.g., depending on a configured mode). In some examples, interfaces 215 may be portions of a local controller 150 of the memory device 145-a, and interfaces 255 may be portions of a host system controller 120 of the host system 105-a.

In some examples, the memory device 145-a may be configured (e.g., dynamically, by command, by manufacturing setting, by operation setting, by address) to operate in a two-channel mode (e.g., a channel-pair mode) or a one-channel mode. In some examples, configuration of the architecture 200 for the two-channel mode or the one-channel mode may be based on one or more bits of a mode register (e.g., as read during bootup, as read based on a reset command) or an indication from the host system 105-a (e.g., via a CA bus of the channel 205-a, the channel 205-b, or both). The memory device 145-a may be configured to operate in any integer multiples of the two-channel mode and the one-channel mode, including such modes that may be based on a quantity of memory dies of the memory device 145-a. For example, the memory device 145-a may include two semiconductor dies, the two dies each configurable in one of the one-channel mode or the two-channel mode. In such examples, the memory device 145-a may be configured to operate in a four-channel mode (e.g., with both dies configured in a two-channel mode) or a two-channel mode (e.g., with both dies configured in the one-channel mode), or with one die configured in a one-channel mode and the other die configured in a two-channel mode, among other examples.

In an example of a two-channel mode, the memory device 145-a may be configured to access (e.g., store, read) first data communicated via the channel 205-a (e.g., via the interface 215-a) in the memory array 210-a and may access second data communicated via the channel 205-b (e.g., via the interface 215-b) in the memory array 210-b. For example, the host system 105-a may transmit a first write command to the memory device 145-a via the CA bus of the channel 205-a, with first data associated with the first write command transmitted via the I/O bus of the channel 205-a, and the memory device 145-a may store the first data at an address of the memory array 210-a based on the first write command. The host system 105a may transmit a second write command to the memory device 145-a via the CA bus of the channel 205-b, with second data associated with the second write command via the I/O bus of the channel 205-b, and the memory device 145-a may store the second data at an address of the memory array 210-b based on the second write command. In the two-channel mode, the interface 215-a may thus be associated with the memory array 210-a (e.g., without being associated with the memory array 210-b) and the interface 215-b may be associated with the memory array 210-b (e.g., without being associated with the memory array 210-a ). Accordingly, the two-channel mode may be associated with the channel 205-a and the channel 205-b such that both the channel 205-a and the channel 205-b may support communication between the memory device 145-a and the host system 105a (e.g., for accessing respective memory arrays 210, for concurrent access, for parallel access). In other words, the two-channel mode may utilize two channel sets, and cach channel set may correspond to (e.g., may support access of) address space of a respective memory array 210.

In an example of a one-channel mode, the memory device 145-a may be configured to access data communicated via the channel 205-b (e.g., via the interface 215-b, without operating the interface 215-a, while the interface 215-a is disabled) in either the memory array 210-a or the memory array 210-b based on an address indication associated with access commands, which may, in some examples, be conveyed separately from a CA bus of the channel 205-b (e.g., via an A/B bus, which may be associated with the channel 205-b or shared between the channels 205-a and 205-b). For example, the host system 105-a may transmit a write command to the memory device 145-a via the CA bus of the channel 205-b and may indicate, via the A/B bus, whether the data associated with the write command is to be stored in the memory array 210-a or the memory array 210-b. The memory device 145-a may store the data in the memory array 210-a or the memory array 210-b based on the indication (e.g., A/B indication) from the host system 105-a. Accordingly, the one-channel mode may be associated with the channel 205-b (e.g., and not the channel 205-a) such that the channel 205-b may support communication between the memory device 145-aand the host system 105a (e.g., for accessing multiple memory arrays 210), while the channel 205-a may be unused or used for different access operations or configurations. In other words, the one-channel mode may utilize a single channel set, and the channel set may correspond to (e.g., may support access of) address space of multiple memory arrays 210.

In some implementations, the memory device 145-a may include logic 220 (e.g., arbitration logic), which also may be a portion of a local controller 150. The logic 220 may receive the indication from the A/B bus as input and may determine whether an access command communicated via the channel 205-b is directed to accessing the memory array 210-a or the memory array 210-b. The logic 220 may, in the case of a read command, return data from one of the memory array 210-a or the memory array 210-b based on the memory array 210 that is indicated by the A/B indication. In the case of a write command, the logic 220 may send data received from the host system 105a (e.g., via the channel 205-b) to one of the memory array 210-a or the memory array 210-b based on the A/B indication.

The memory arrays 210-a and 210-b may be implemented in various ways to support configurations in a one-channel mode, a two-channel mode, or both. For example, the memory array 210-a may be associated with a first physical location in the memory device 145-a and may be segmented from the memory array 210-b, which may be associated with a second physical location in the memory device 145-a. In some examples, separation (e.g., logical separation) between the memory array 210-a and the memory array 210-b may be based on a dynamic allocation (e.g., a selection) of one or more portions of a memory array 155 to establish operation as a memory array 210-a and a memory array 210-b. Such dynamic allocation of memory arrays 210 may be based on one or more operations of the memory device 145-a, one or more commands received from the host system 105-a, or both.

In some examples (e.g., in a two-channel mode), each of the channel 205-a and the channel 205-bmay be configured for communication of access commands and corresponding data (e.g., write data, read data), and may be associated with accessing a respective memory array 210. For example, the channel 205-a may support communication of access commands being performed on a first memory array 210-a , or portion thereof, and the channel 205-b may support communication of access commands being performed on a second memory array 210-b, or portion thereof. In some cases (e.g., safety-critical systems, systems involving a relatively high degree of data integrity), it may be beneficial for the memory device 145-a to support relatively low error rates for access operations being performed using a particular channel 205.

In accordance with examples described herein, the memory device 145-a may be configured to access both the memory array 210-a and the memory array 210-b using a single channel 205 that may otherwise be associated with separate channels 205, and the memory device 145-a may store copies of data (e.g., redundant data) in both the memory array 210-a and the memory array 210-b. For example, to write data to memory, the memory device 145-a may be configured to write a first copy of the data to the memory array 210-a that is accessed via the channel 205-b and a second copy of data to the memory array 210-b that is also accessed via the channel 205-b. To read data from memory, the memory device 145-a may be configured to read the first copy of the data from the memory array 210-a , the second copy of the data from the memory array 210-b, or both, which may support relatively low error rates and a relatively high data integrity and reliability of the memory device 145-a.

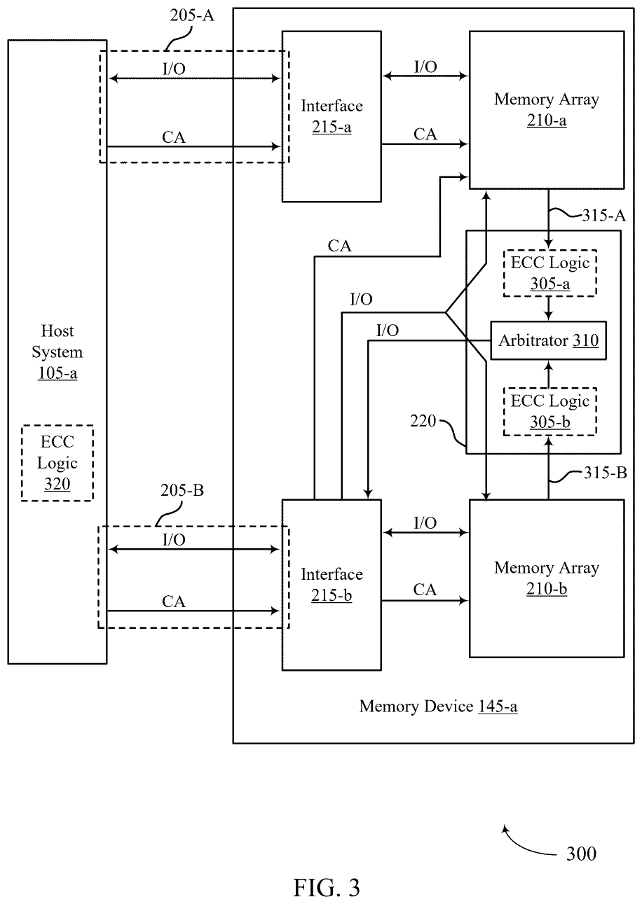

FIG. 3 shows an example of an architecture 300 that supports redundancy techniques for multi-channel memory devices in accordance with examples as disclosed herein. The architecture 300 may implement or may be implemented by aspects of a system 100. For example, the architecture 300 may include a memory device 145-a and a host system 105-a, which may be examples of corresponding devices described herein (e.g., as described with reference to FIG. 2). For example, the architecture 300 may illustrate aspects of configurations of the memory device 145-a and host system 105a to support a one-channel redundancy mode, which may be supported by the host system 105-a, the memory device 145-a, or both in addition to the one-channel mode, the two-channel mode, or both in accordance with the architecture 200.

In examples of a one-channel redundancy mode, the memory device 145-a may store respective copies of data (e.g., redundant data) communicated via the channel 205-b in the memory array 210-a and in the memory array 210-b. For example, the memory device 145-a may receive, via the channel 205-b, data (e.g., via an I/O bus) and a command (e.g., via the CA bus) to write the data to the memory device 145-a. The memory device 145-a may receive the data and the command via the interface 215-b. The memory device 145-a may store a first copy of the data to the memory array 210-a and a second copy of the data to the memory array 210-b based on receiving the data and the write command. In various examples of the one-channel redundancy mode, the interface 215-a may be disabled, or may be implemented separately for operations of a different mode (e.g., for operations in accordance with a two-channel mode), among other examples.

In some examples, the memory device 145-a may be configured to operate in the one-channel redundancy mode based on an indication from the host system 105-a. For example, the memory device 145-a may be configured to operate in the one-channel redundancy mode based on a command received via the channel 205-b or based on one or more bits of a mode register (e.g., written by the host system 105-a). Additionally, or alternatively, the memory device 145-a may be configured to operate in the one-channel redundancy mode based on other indications, which may be signaled or stored during a manufacturing operation, during a configuration operation, or both. In some examples, the memory array 210-a may be a portion of a memory array 155. The memory device 145-a may be configured to operate the portion of the memory array 155 that includes the memory array 210-a in the one-channel redundancy mode and to operate another portion of the memory array 155 in a one-channel mode, a two-channel mode, or both. In some examples, an indication from the host system 105a (e.g., via a configuration signaling, via mode register) may indicate, to the memory device 145-a, a first portion of the memory array 155 (e.g., a percentage, a quantity of memory cells, a set of addresses) that is to be configured in the one-channel redundancy mode (e.g., a redundancy protected mode), a second portion of the memory array 155 that is to be configured in the two-channel mode or the one-channel mode (e.g., as described with reference to architecture 200, a non-redundancy protected mode), or both.

In the one-channel redundancy mode, the memory device 145-a may receive (e.g., via the CA bus of the channel 205-b) a command to read data from the memory device 145-a. In such a mode, the memory device 145-a may be configured to output a first copy of the read data from the memory array 210-a, a second copy of the read data form the memory array 210-b, or both based on the command to read the data. In some examples, before outputting the read data to the host system 105a (e.g., via the channel 205-b), logic 220 may receive data 315-a (e.g., a first copy of the data) from the memory array 210-a and data 315-b (e.g., a second copy of the data) from the memory array 210-b. The logic 220 may include an arbitrator 310 which may determine whether to output the data 315-a, the data 315-b, or both, based on various operating conditions. In various examples, such a determination may be based on a comparison between the data 315-a and the data 315-b (e.g., with a difference prompting an evaluation of sending one or the other), an error condition associated with one or both of the data 315-a and the data 315-b (e.g., a quantity of bit errors, a presence of bit errors, an indication of whether the error is correctible or uncorrectable at the memory device 145-a), historical results (e.g., a historical record of errors associated with the memory array 210-a or the memory array 210-b) of one or both of the memory array 210-a and the memory array 210-b, or an indication from the host system 105a (e.g., a request or command to forward data from the memory array 210-a or memory array 210-b), among other parameters.

In some examples, the arbitrator 310 may, in response to a read command (e.g., a first read command) from the host system 105-a, be configured to output a copy of first data (e.g., the data 315-a) from the memory array 210-a (e.g., based on a default or first configuration of the arbitrator 310). The arbitrator 310 may determine (e.g., autonomously, without input from the host system 105-a, in accordance with a second configuration) to switch to outputting respective copies of data (e.g., of second data different from the first data) from the memory array 210-b for one or more other read commands (e.g., a second read command) received from the host system 105a that follow the first command (e.g., or to update the default or first configuration of the arbitrator 310). The switching to outputting (e.g., initially) from the memory array 210-b for future commands may be based on a comparison between the data 315-a and the data 315-b, an error condition associated with one or both of the data 315-a and the data 315-b, historical results (e.g., an error correction code (ECC) count) of one or both of the memory array 210-a and the memory array 210-b, or an indication from the host system 105-a, among other parameters.

In some implementations, the determination by the arbitrator 310 of whether to output a copy of read data from the memory array 210-a, a copy of read data from the memory array 210-b, or both may be based on ECC logic 305 at the memory device (e.g., instances of ECC logic 305-a and 305-b, which may be examples of on-die ECC circuitry or circuitry otherwise operable to support ECC functionality at the memory device 145-a). The ECC logic 305-a may correspond to the memory array 210-a and the ECC logic 305-b may correspond to the memory array 210-b. In some examples, one or more instances of ECC logic 305 may be included in the logic 220. In some other examples, one or more instances of ECC logic may be located outside of the logic 220. For example, the ECC logic 305-a may be included in logic associated with (e.g., co-located, a component of) the memory array 210-a and the ECC logic 305-b may be included in logic associated with the memory array 210-b. In some examples, in a two-channel mode as described in greater detail with reference to FIG. 2, the memory device 145-a may be operable to output error correction data (e.g., pertaining to the memory array 210-a) from the ECC logic 305-a directly to the host system 105a via the channel 205-a and error correction data (e.g., pertaining to the memory array 210-b) from the ECC logic 305-b directly to the host system 105a via the channel 205-b.

In some examples, based on retrieving the data 315-a from the memory array 210-a, the ECC logic 305-a may determine an error condition (e.g., an ECC error, one or more bit errors) associated with the memory array 210-a (e.g., associated with the data 315-a). In some examples, the error condition may be an uncorrectable error. The arbitrator may determine (e.g., based on the error condition, based on a quantity of bit errors, based on an uncorrectable error) to output a second copy of data from the memory array 210-b to the host system 105a based on the error condition associated with the memory array 210-a. In some examples, based on retrieving the data 315-a from the memory array 210-a and the data 315-b from the memory array 210-b, the ECC logic 305-a may determine a first error condition associated with the memory array 210-a and the ECC logic 305-b may determine a second error condition associated with the memory array 210-b. In such examples, the arbitrator 310 may compare the first and second error conditions and may output the first copy of the data from the memory array 210-a based on a severity of the first error condition being less than a severity of the second error condition, or being below or otherwise satisfying an error threshold. Additionally, or alternatively, the arbitrator 310 may determine to output both the first copy of the data and the second copy of the data to the host system 105a based on the first and second error conditions. In some examples (e.g., in cases where the ECC logic 305-a or the ECC logic 305-b are not included in the memory device 145-a), the arbitrator 310 may determine that the data 315-a from the memory array 210-a and the data 315-b from the memory array 210-b are different and may determine to output both the data 315-a and the data 315-b to the host system 105a based on the data 315-a and the data 315-b being different.

In some examples, based on determining an error condition associated with the memory array 210-a or the memory array 210-b, or both, the memory device 145-a may report an error to the host system 105-a. For example, the memory device 145-a may invert a cyclic redundancy check (CRC) output to indicate the error, may report the error via an error detection code (EDC) output, or may indicate the error via a severity flag. The host system 105a may receive a reported error of the memory array 210-a based on transmitting a first command to read first data, and the host system 105a may transmit an indication to the memory device 145-a to output a second copy of the first data from the memory array 210-b (e.g., to perform a replay of the first command) based on receiving the reported error. Additionally, or alternatively, the host system 105a may indicate to switch to outputting respective second copies of data (e.g., second data different from the first data) from the memory array 210-b (e.g., changing which memory array 210 provides an initial copy of read data) for one or more second commands that follow the first command (e.g., to update a configuration of the arbitrator 310) based on the reported error.

In some examples, the memory device 145-a may maintain (e.g., may store in a memory array 210) an error counter that indicates a quantity of errors associated with one of the memory array 210-a or the memory array 210-b. For example, the memory device 145-a may store a first error counter corresponding to the memory array 210-a and a second error counter corresponding to the memory array 210-b. In some examples, an error condition associated with a memory array 210-a may be based on the first error counter satisfying a threshold, a comparison between the first error counter and the second error counter, or both. In some examples, the error condition associated with the memory array 210-a may precede a command to read data, and the memory device 145-a may output a second copy of the data from the memory array 210-b based on the error condition. For example, the error condition may be an uncorrectable error at the memory array 210-a , or the error condition may be based on the first error counter satisfying a threshold or a historical performance of the memory array 210-b being below a threshold.

In some examples (e.g., in addition to the memory device 145-a including one or more instance of ECC logic 305, as an alternative to the memory device 145-a including any instances of ECC logic 305), the host system 105a may include ECC logic 320, and the host system 105a may determine an error condition associated with the memory array 210-a, the memory array 210-b, or both using the ECC logic 320. In some examples, ECC logic 320 may be a portion of a host system controller 120. In some examples, the host system 105-a may receive, from the memory device 145-a, a first copy of first data associated with a first command, and the host system 105a may indicate to the memory device 145-a to output a second copy of the first data (e.g., the data 315-b) from the memory array 210-b (e.g., based on an error condition associated with the memory array 210-a, which may be detected by ECC logic 320). Additionally, or alternatively, the host system 105a may indicate for the memory device 145-a to switch to outputting data (e.g., second data different from the first data) from both the memory array 210-a and the memory array 210-b for one or more second commands that follow the first command (e.g., to update a default configuration of the arbitrator 310), which may be based on error conditions evaluated by ECC logic 320. In some examples, the host system 105a may transmit an indication to reset the memory device 145-a, or an indication to disable the memory array 210-a (e.g., for a duration), or both based on receiving the first copy of the first data, the second copy of the first data, or both.

Thus, in accordance with these and other examples (e.g., in accordance with an architecture 200, an architecture 300, or a combination thereof), a memory system 110 (e.g., one or more memory devices 145) may be configured with multiple channels 205 that can be operated in different modes, including a one-channel redundancy mode. For example, the memory device 145-a may be configured for operations in a two-channel mode (e.g., in accordance with the architecture 200) in which the memory device 145-a stores first data communicated via the channel 205-a in the memory array 210-a and second data communicated via the channel 205-b in the memory array 210-b, The memory device 145-a may also be configured in a one-channel mode (e.g., in accordance with the architecture 200) in which the memory device 145-a stores a single copy of data communicated via the channel 205-b in either of the memory array 210-a or the memory array 210-b based on an address indication. The memory device 145-a may also be configured for operations in a one-channel redundancy mode in which the memory device 145-a stores respective copies of data communicated via the channel 205-b in both the memory array 210-a and the memory array 210-b. The one-channel redundancy mode may enable the memory device 145-a to support relatively low error rates and a relatively high data integrity associated with data stored in one or more memory arrays 210, or one or more configured portions thereof, which may be beneficial in safety-critical systems, or systems involving a relatively high degree of data integrity.

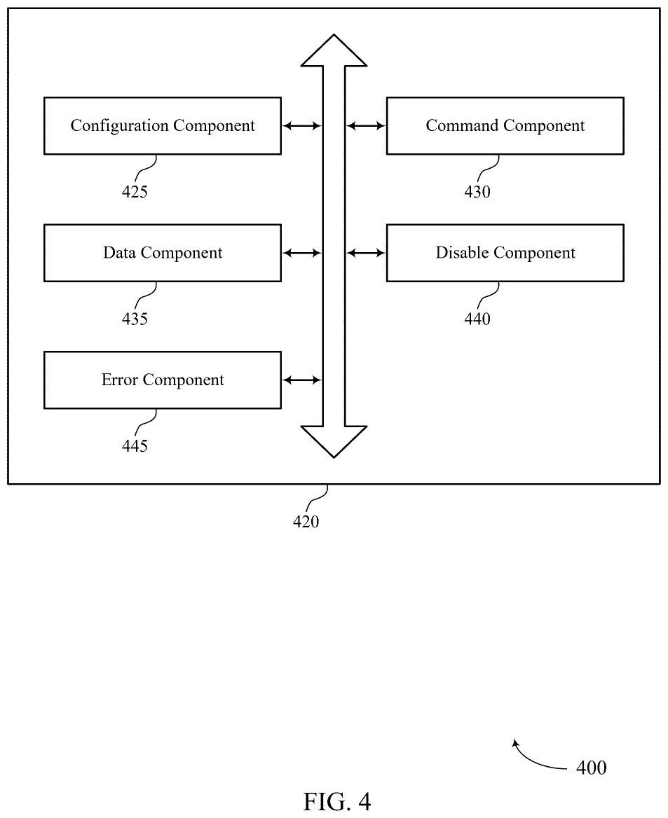

FIG. 4 shows a block diagram 400 of a memory system 420 that supports redundancy techniques for multi-channel memory devices in accordance with examples as disclosed herein. The memory system 420 may be an example of aspects of a memory system (e.g., a memory system 110, a memory device 145) as described with reference to FIGS. 1 through 3. The memory system 420, or various components thereof, may be an example of means for performing various aspects of redundancy techniques for multi-channel memory devices as described herein. For example, the memory system 420 may include a configuration component 425, a command component 430, a data component 435, a disable component 440, an error component 445, or any combination thereof. Each of these components, or components of subcomponents thereof (e.g., one or more processors, one or more memories), may communicate, directly or indirectly, with one another (e.g., via one or more buses).

The configuration component 425 may be configured as or otherwise support a means for configuring a memory device, having a plurality of memory arrays, a first channel interface, and a second channel interface, for operations in a one-channel redundancy mode associated with the second channel interface in which the memory device receives access commands via the second channel interface and accesses respective data copies of a first memory array of the plurality of memory arrays and of a second memory array of the plurality of memory arrays. The command component 430 may be configured as or otherwise support a means for receiving, via the second channel interface, a command to read data from the memory device. The data component 435 may be configured as or otherwise support a means for outputting, based at least in part on receiving the command to read the data and configuring the memory device for operations in the one-channel redundancy mode, a first copy of the data from the first memory array, a second copy of the data from the second memory array, or both via the second channel interface.

In some examples, the command component 430 may be configured as or otherwise support a means for receiving, via the second channel interface, the data and a command to write the data to the memory device. In some examples, the data component 435 may be configured as or otherwise support a means for storing, based at least in part on receiving the command to write the data and configuring the memory device for operations in the one-channel redundancy mode, the first copy of data to the first memory array and the second copy of the data to the second memory array.

In some examples, the data component 435 may be configured as or otherwise support a means for outputting the first copy of the data from the first memory array. In some examples, the command component 430 may be configured as or otherwise support a means for receiving an indication to output the second copy of the data. In some examples, the data component 435 may be configured as or otherwise support a means for outputting, based at least in part on the indication, the second copy of the data from the second memory array.

In some examples, the disable component 440 may be configured as or otherwise support a means for receiving an indication to disable the first memory array based at least in part on outputting the first copy of the data from the first memory array and outputting the second copy of the data from the second memory array (e.g., and disabling aspects of operating the first memory array).

In some examples, the command component 430 may be configured as or otherwise support a means for receiving an indication to output a first copy of second data from the second memory array based at least in part on outputting the first copy of the data from the first memory array and outputting the second copy of the data from the second memory array.

In some examples, the data component 435 may be configured as or otherwise support a means for outputting the first copy of the data from the first memory array based at least in part on an error condition associated with the second memory array.

In some examples, the error component 445 may be configured as or otherwise support a means for reporting the error condition associated with the second memory array, where outputting the first copy of the data is based at least in part on reporting the error condition.

In some examples, the error condition is based at least in part on a first quantity of errors associated with the second memory array satisfying a threshold, a comparison between the first quantity of errors and a second quantity of errors associated with the first memory array, or both.

In some examples, the error component 445 may be configured as or otherwise support a means for identifying the uncorrectable error based at least in part on outputting the second copy of the data from the second memory array.

In some examples, the error condition associated with the second memory array precedes the command to read the data.

In some examples, the first channel interface and the second channel interface each include a respective command and address bus and a respective data bus.

In some examples, the described functionality of the memory system 420 (e.g., a memory system 110, a memory device 145), or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

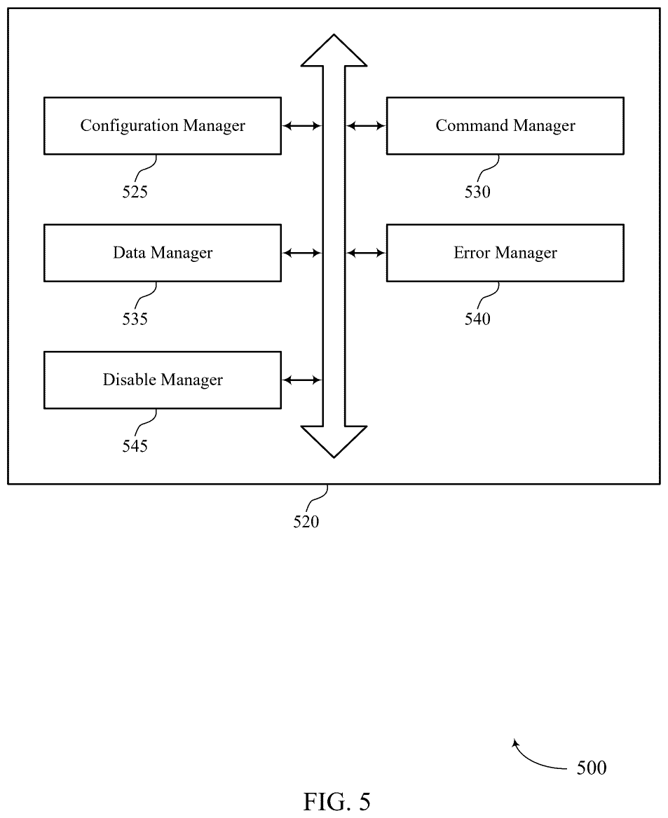

FIG. 5 shows a block diagram 500 of a host system 520 that supports redundancy techniques for multi-channel memory devices in accordance with examples as disclosed herein. The host system 520 may be an example of aspects of a host system (e.g., a host system 105) as described with reference to FIGS. 1 through 3. The host system 520, or various components thereof, may be an example of means for performing various aspects of redundancy techniques for multi-channel memory devices as described herein. For example, the host system 520 may include a configuration manager 525, a command manager 530, a data manager 535, an error manager 540, a disable manager 545, or any combination thereof. Each of these components, or components of subcomponents thereof (e.g., one or more processors, one or more memories), may communicate, directly or indirectly, with one another (e.g., via one or more buses).

The configuration manager 525 may be configured as or otherwise support a means for transmitting an indication to configure a memory device, having a plurality of memory arrays, a first channel interface, and a second channel interface, for operations in a one-channel redundancy mode associated with the second channel interface in which the memory device receives access commands via the second channel interface and accesses respective data copies of a first memory array of the plurality of memory arrays and of a second memory array of the plurality of memory arrays. The command manager 530 may be configured as or otherwise support a means for transmitting, via the second channel interface, a command to read data from the memory device. The data manager 535 may be configured as or otherwise support a means for receiving, based at least in part on transmitting the indication to configure the memory device for operations in the one-channel redundancy mode and transmitting the command to read the data and, a first copy of the data from the first memory array, a second copy of the data from the second memory array, or both via the second channel interface.

In some examples, the data manager 535 may be configured as or otherwise support a means for receiving the first copy of the data from the first memory array. In some examples, the command manager 530 may be configured as or otherwise support a means for transmitting an indication to output the second copy of the data. In some examples, the data manager 535 may be configured as or otherwise support a means for receiving, based at least in part on transmitting the indication to output the second copy of the data, the second copy of the data from the second memory array.

In some examples, the disable manager 545 may be configured as or otherwise support a means for transmitting an indication to disable the first memory array based at least in part on receiving the first copy of the data from the first memory array and receiving the second copy of the data from the second memory array.

In some examples, the command manager 530 may be configured as or otherwise support a means for transmitting an indication to output a first copy of second data from the second memory array based at least in part on receiving the first copy of the data from the first memory array and receiving the second copy of the data from the second memory array.

In some examples, the data manager 535 may be configured as or otherwise support a means for receiving the first copy of the data from the first memory array. In some examples, the error manager 540 may be configured as or otherwise support a means for receiving a report of an error condition associated with the first memory array. In some examples, the command manager 530 may be configured as or otherwise support a means for transmitting an indication to output the second copy of the data from the second memory array based at least in part on the report of the error condition.

In some examples, the first channel interface and the second channel interface each include a respective command and address bus and a respective data bus.

In some examples, the described functionality of the host system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the host system 520, or various components thereof, may be implemented at least in part by instructions (e.g., stored in memory, non-transitory computer-readable medium) executable by such at least one processor.

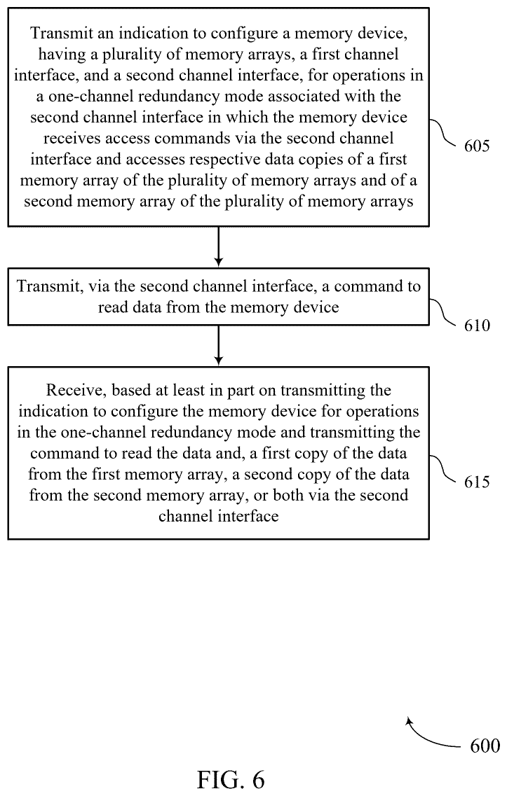

FIG. 6 shows a flowchart illustrating a method 600 that supports redundancy techniques for multi-channel memory devices in accordance with examples as disclosed herein. The operations of method 600 may be implemented by a host system or its components as described herein. For example, the operations of method 600 may be performed by a host system as described with reference to FIGS. 1 through 3 and 5. In some examples, a host system may execute a set of instructions to control the functional elements of the device to perform the described functions. Additionally, or alternatively, the host system may perform aspects of the described functions using special-purpose hardware.

At 605, the method may include transmitting an indication to configure a memory device, having a plurality of memory arrays, a first channel interface, and a second channel interface, for operations in a one-channel redundancy mode associated with the second channel interface in which the memory device receives access commands via the second channel interface and accesses respective data copies of a first memory array of the plurality of memory arrays and of a second memory array of the plurality of memory arrays. In some examples, aspects of the operations of 605 may be performed by a configuration manager 525 as described with reference to FIG. 5.

At 610, the method may include transmitting, via the second channel interface, a command to read data from the memory device. In some examples, aspects of the operations of 610 may be performed by a command manager 530 as described with reference to FIG. 5.

At 615, the method may include receiving, based at least in part on transmitting the indication to configure the memory device for operations in the one-channel redundancy mode and transmitting the command to read the data and, a first copy of the data from the first memory array, a second copy of the data from the second memory array, or both via the second channel interface. In some examples, aspects of the operations of 615 may be performed by a data manager 535 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects as disclosed herein:

Aspect 1: A method, apparatus, or non-transitory computer-readable medium including operations, features, circuitry, logic, means, or instructions, or any combination thereof for transmitting an indication to configure a memory device, having a plurality of memory arrays, a first channel interface, and a second channel interface, for operations in a one-channel redundancy mode associated with the second channel interface in which the memory device receives access commands via the second channel interface and accesses respective data copies of a first memory array of the plurality of memory arrays and of a second memory array of the plurality of memory arrays; transmitting, via the second channel interface, a command to read data from the memory device; and receiving, based at least in part on transmitting the indication to configure the memory device for operations in the one-channel redundancy mode and transmitting the command to read the data and, a first copy of the data from the first memory array, a second copy of the data from the second memory array, or both via the second channel interface.

Aspect 2: The method, apparatus, or non-transitory computer-readable medium of aspect 1, further including operations, features, circuitry, logic, means, or instructions, or any combination thereof for receiving the first copy of the data from the first memory array; transmitting an indication to output the second copy of the data; and receiving, based at least in part on transmitting the indication to output the second copy of the data, the second copy of the data from the second memory array.

Aspect 3: The method, apparatus, or non-transitory computer-readable medium of aspect 2, further including operations, features, circuitry, logic, means, or instructions, or any combination thereof for transmitting an indication to disable the first memory array based at least in part on receiving the first copy of the data from the first memory array and receiving the second copy of the data from the second memory array.

Aspect 4: The method, apparatus, or non-transitory computer-readable medium of any of aspects 2 through 3, further including operations, features, circuitry, logic, means, or instructions, or any combination thereof for transmitting an indication to output a first copy of second data from the second memory array based at least in part on receiving the first copy of the data from the first memory array and receiving the second copy of the data from the second memory array.

Aspect 5: The method, apparatus, or non-transitory computer-readable medium of any of aspects 1 through 4, further including operations, features, circuitry, logic, means, or instructions, or any combination thereof for receiving the first copy of the data from the first memory array; receiving a report of an error condition associated with the first memory array; and transmitting an indication to output the second copy of the data from the second memory array based at least in part on the report of the error condition.

Aspect 6: The method, apparatus, or non-transitory computer-readable medium of any of aspects 1 through 5, where the first channel interface and the second channel interface each include a respective command and address bus and a respective data bus.

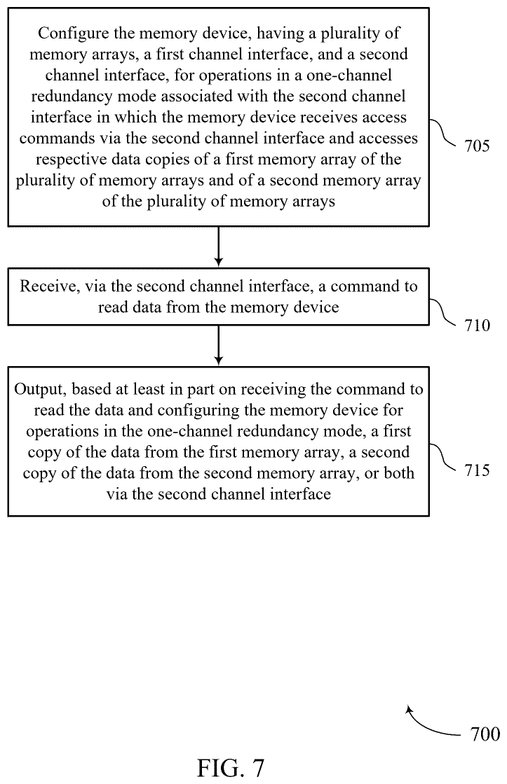

FIG. 7 shows a flowchart illustrating a method 700 that supports redundancy techniques for multi-channel memory devices in accordance with examples as disclosed herein. The operations of method 700 may be implemented by a memory system (e.g., a memory device) or its components as described herein. For example, the operations of method 700 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 705, the method may include configuring a memory device, having a plurality of memory arrays, a first channel interface, and a second channel interface, for operations in a one-channel redundancy mode associated with the second channel interface in which the memory device receives access commands via the second channel interface and accesses respective data copies of a first memory array of the plurality of memory arrays and of a second memory array of the plurality of memory arrays. In some examples, aspects of the operations of 705 may be performed by a configuration component 425 as described with reference to FIG. 4.

At 710, the method may include receiving, via the second channel interface, a command to read data from the memory device. In some examples, aspects of the operations of 710 may be performed by a command component 430 as described with reference to FIG. 4.

At 715, the method may include outputting, based at least in part on receiving the command to read the data and configuring the memory device for operations in the one-channel redundancy mode, a first copy of the data from the first memory array, a second copy of the data from the second memory array, or both via the second channel interface. In some examples, aspects of the operations of 715 may be performed by a data component 435 as described with reference to FIG. 4.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects as disclose herein:

Aspect 7: A method, apparatus, or non-transitory computer-readable medium including operations, features, circuitry, logic, means, or instructions, or any combination thereof for configuring the memory device, having a plurality of memory arrays, a first channel interface, and a second channel interface, for operations in a one-channel redundancy mode associated with the second channel interface in which the memory device receives access commands via the second channel interface and accesses respective data copies of a first memory array of the plurality of memory arrays and of a second memory array of the plurality of memory arrays; receiving, via the second channel interface, a command to read data from the memory device; and outputting, based at least in part on receiving the command to read the data and configuring the memory device for operations in the one-channel redundancy mode, a first copy of the data from the first memory array, a second copy of the data from the second memory array, or both via the second channel interface.

Aspect 8: The method, apparatus, or non-transitory computer-readable medium of aspect 7, further including operations, features, circuitry, logic, means, or instructions, or any combination thereof for receiving, via the second channel interface, the data and a command to write the data to the memory device and storing, based at least in part on receiving the command to write the data and configuring the memory device for operations in the one-channel redundancy mode, the first copy of data to the first memory array and the second copy of the data to the second memory array.

Aspect 9: The method, apparatus, or non-transitory computer-readable medium of any of aspects 7 through 8, further including operations, features, circuitry, logic, means, or instructions, or any combination thereof for outputting the first copy of the data from the first memory array; receiving an indication to output the second copy of the data; and outputting, based at least in part on the indication, the second copy of the data from the second memory array.

Aspect 10: The method, apparatus, or non-transitory computer-readable medium of aspect 9, further including operations, features, circuitry, logic, means, or instructions, or any combination thereof for receiving an indication to disable the first memory array based at least in part on outputting the first copy of the data from the first memory array and outputting the second copy of the data from the second memory array.

Aspect 11: The method, apparatus, or non-transitory computer-readable medium of any of aspects 9 through 10, further including operations, features, circuitry, logic, means, or instructions, or any combination thereof for receiving an indication to output a first copy of second data from the second memory array based at least in part on outputting the first copy of the data from the first memory array and outputting the second copy of the data from the second memory array.

Aspect 12: The method, apparatus, or non-transitory computer-readable medium of any of aspects 7 through 11, further including operations, features, circuitry, logic, means, or instructions, or any combination thereof for outputting the first copy of the data from the first memory array based at least in part on an error condition associated with the second memory array.

Aspect 13: The method, apparatus, or non-transitory computer-readable medium of aspect 12, further including operations, features, circuitry, logic, means, or instructions, or any combination thereof for reporting the error condition associated with the second memory array, where outputting the first copy of the data is based at least in part on reporting the error condition.

Aspect 14: The method, apparatus, or non-transitory computer-readable medium of any of aspects 12 through 13, where the error condition is based at least in part on a first quantity of errors associated with the second memory array satisfying a threshold, a comparison between the first quantity of errors and a second quantity of errors associated with the first memory array, or both.

Aspect 15: The method, apparatus, or non-transitory computer-readable medium of any of aspects 12 through 14, further including operations, features, circuitry, logic, means, or instructions, or any combination thereof for identifying the uncorrectable error based at least in part on outputting the second copy of the data from the second memory array.

Aspect 16: The method, apparatus, or non-transitory computer-readable medium of any of aspects 12 through 15, where the error condition associated with the second memory array precedes the command to read the data.

Aspect 17: The method, apparatus, or non-transitory computer-readable medium of any of aspects 12 through 16, where the first channel interface and the second channel interface each include a respective command and address bus and a respective data bus.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 18: A memory device, including: a plurality of memory arrays; a first channel interface; a second channel interface; and processing circuitry coupled with the plurality of memory arrays, the first channel interface, and the second channel interface, the processing circuitry operable to cause the memory device to: configure the memory device for first operations in a two-channel mode, associated with the first channel interface and the second channel interface, in which the memory device stores first data communicated via the first channel interface in a first memory array of the plurality of memory arrays and stores second data communicated via the second channel interface in a second memory array of the plurality of memory arrays; and configure the memory device for second operations in a one-channel mode, associated with the second channel interface, in which the memory device stores respective copies of third data communicated via the second channel interface in the first memory array and in the second memory array.

Aspect 19: The memory device of aspect 18, where the processing circuitry is further operable to cause the memory device to: configure the memory device for third operations in a second one-channel mode, associated with the second channel interface, in which the memory device stores a single copy of fourth data communicated via the second channel interface in one of the first memory array or the second memory array based at least in part on an address indication of the fourth data.

Aspect 20: The memory device of aspect 19, where the processing circuitry is further operable to cause the memory device to: configure a first portion of the first memory array for the second operations in the one-channel mode and a second portion of the first memory array for the second operations in the second one-channel mode.

Aspect 21: The memory device of any of aspects 18 through 20, where the processing circuitry is further operable to cause the memory device to: configure a first portion of the first memory array for the first operations in the two-channel mode and a second portion of the first memory array for the second operations in the one-channel mode.

Aspect 22: The memory device of any of aspects 18 through 21, where the processing circuitry is further operable to cause the memory device to: receive an indication to configure the memory device in the one-channel mode, where configuring the memory device for the second operations in the one-channel mode is based at least in part on receiving the indication.

Aspect 23: The memory device of aspect 22, where the indication to configure the memory device in the one-channel mode is associated with a command to access the memory device.

Aspect 24: The memory device of any of aspects 18 through 23, where the processing circuitry is further operable to cause the memory device to: configure the memory device for the second operations in the one-channel mode based at least in part on one or more bits of a mode register.

Aspect 25: The memory device of any of aspects 18 through 24, where the first channel interface and the second channel interface each include a respective command and address bus and a respective data bus.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, cach of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
a plurality of memory arrays;
a first channel interface;
a second channel interface; and
processing circuitry coupled with the plurality of memory arrays, the first channel interface, and the second channel interface, the processing circuitry operable to cause the memory device to:
configure the memory device for first operations in a two-channel mode, associated with the first channel interface and the second channel interface, in which the memory device stores first data communicated via the first channel interface in a first memory array of the plurality of memory arrays and stores second data communicated via the second channel interface in a second memory array of the plurality of memory arrays; and
configure the memory device for second operations in a one-channel mode, associated with the second channel interface, in which the memory device stores respective copies of third data communicated via the second channel interface in the first memory array and in the second memory array.

2. The memory device of claim 1, wherein the processing circuitry is further operable to cause the memory device to:
configure the memory device for third operations in a second one-channel mode, associated with the second channel interface, in which the memory device stores a single copy of fourth data communicated via the second channel interface in one of the first memory array or the second memory array based at least in part on an address indication of the fourth data.

3. The memory device of claim 2, wherein the processing circuitry is further operable to cause the memory device to:
configure a first portion of the first memory array for the second operations in the one-channel mode and a second portion of the first memory array for the second operations in the second one-channel mode.

4. The memory device of claim 1, wherein the processing circuitry is further operable to cause the memory device to:
configure a first portion of the first memory array for the first operations in the two-channel mode and a second portion of the first memory array for the second operations in the one-channel mode.

5. The memory device of claim 1, wherein the processing circuitry is further operable to cause the memory device to:
receive an indication to configure the memory device in the one-channel mode, wherein configuring the memory device for the second operations in the one-channel mode is based at least in part on receiving the indication.

6. The memory device of claim 5, wherein the indication to configure the memory device in the one-channel mode is associated with a command to access the memory device.

7. The memory device of claim 1, wherein the processing circuitry is further operable to cause the memory device to:
configure the memory device for the second operations in the one-channel mode based at least in part on one or more bits of a mode register.

8. The memory device of claim 1, wherein the first channel interface and the second channel interface each include a respective command and address bus and a respective data bus.

9. A method of operating a host device, comprising:
transmitting an indication to configure a memory device, having a plurality of memory arrays, a first channel interface, and a second channel interface, for operations in a one-channel redundancy mode associated with the second channel interface in which the memory device receives access commands via the second channel interface and accesses respective data copies of a first memory array of the plurality of memory arrays and of a second memory array of the plurality of memory arrays;
transmitting, via the second channel interface, a command to read data from the memory device; and
receiving, based at least in part on transmitting the indication to configure the memory device for operations in the one-channel redundancy mode and transmitting the command to read the data and, a first copy of the data from the first memory array, a second copy of the data from the second memory array, or both via the second channel interface.

10. The method of claim 9, further comprising:
receiving the first copy of the data from the first memory array;
transmitting an indication to output the second copy of the data; and
receiving, based at least in part on transmitting the indication to output the second copy of the data, the second copy of the data from the second memory array.

11. The method of claim 10, further comprising:
transmitting an indication to disable the first memory array based at least in part on receiving the first copy of the data from the first memory array and receiving the second copy of the data from the second memory array.

12. The method of claim 10, further comprising:
transmitting an indication to output a first copy of second data from the second memory array based at least in part on receiving the first copy of the data from the first memory array and receiving the second copy of the data from the second memory array.

13. The method of claim 9, further comprising:
receiving the first copy of the data from the first memory array;
receiving a report of an error condition associated with the first memory array; and
transmitting an indication to output the second copy of the data from the second memory array based at least in part on the report of the error condition.

14. The method of claim 9, wherein the first channel interface and the second channel interface each include a respective command and address bus and a respective data bus.

15. A method of operating a memory device, comprising:
configuring the memory device, having a plurality of memory arrays, a first channel interface, and a second channel interface, for operations in a one-channel redundancy mode associated with the second channel interface in which the memory device receives access commands via the second channel interface and accesses respective data copies of a first memory array of the plurality of memory arrays and of a second memory array of the plurality of memory arrays;
receiving, via the second channel interface, a command to read data from the memory device; and
outputting, based at least in part on receiving the command to read the data and configuring the memory device for operations in the one-channel redundancy mode, a first copy of the data from the first memory array, a second copy of the data from the second memory array, or both via the second channel interface.

16. The method of claim 15, further comprising:
receiving, via the second channel interface, the data and a command to write the data to the memory device; and
storing, based at least in part on receiving the command to write the data and configuring the memory device for operations in the one-channel redundancy mode, the first copy of data to the first memory array and the second copy of the data to the second memory array.

17. The method of claim 15, further comprising:
outputting the first copy of the data from the first memory array;
receiving an indication to output the second copy of the data; and
outputting, based at least in part on the indication, the second copy of the data from the second memory array.

18. The method of claim 17, further comprising:
receiving an indication to disable the first memory array based at least in part on outputting the first copy of the data from the first memory array and outputting the second copy of the data from the second memory array.

19. The method of claim 17, further comprising:
receiving an indication to output a first copy of second data from the second memory array based at least in part on outputting the first copy of the data from the first memory array and outputting the second copy of the data from the second memory array.

20. The method of claim 15, further comprising:
outputting the first copy of the data from the first memory array based at least in part on an error condition associated with the second memory array.

21. The method of claim 20, further comprising:
reporting the error condition associated with the second memory array, wherein outputting the first copy of the data is based at least in part on reporting the error condition.

22. The method of claim 20, wherein the error condition is based at least in part on a first quantity of errors associated with the second memory array satisfying a threshold, a comparison between the first quantity of errors and a second quantity of errors associated with the first memory array, or both.

23. The method of claim 20, wherein the error condition is an uncorrectable error, further comprising:
identifying the uncorrectable error based at least in part on outputting the second copy of the data from the second memory array.

24. The method of claim 20, wherein the error condition associated with the second memory array precedes the command to read the data.

25. The method of claim 20, wherein the first channel interface and the second channel interface each include a respective command and address bus and a respective data bus.
